(19) United States
(12) Patent Application Publication
(10) Pub. No.: US 2009/0167576 A1
(43) Pub. Date: Jul. 2, 2009

(54) METHOD OF STEPWISE ELIMINATING VOLTAGE OFFSET AND VOLTAGE OFFSET ELIMINATION DEVICE IN ANALOG TO DIGITAL PIPELINE CONVERTER

(75) Inventors: Young Jun Lee, Seoul (KR); Hyeong Won Kang, Seoul (KR)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(73) Assignee: NEXTCHIP CO., LTD., Seoul (KR)

(21) Appl. No.: 12/343,569

(22) Filed: Dec. 24, 2008

(30) Foreign Application Priority Data
Dec. 27, 2007 (KR) 10-2007-0139224

(51) Int. Cl. H03M 1/06

(52) U.S. Cl. 341/118

(57) ABSTRACT

Disclosed is a device of stepwise eliminating an offset voltage in an analog-to-digital pipeline converter. The device includes a sub analog-to-digital converter to convert an input signal inputted from a preceding stage into a first digital signal, a sub digital-to-analog converter to convert the first digital signal into a first analog signal, and an offset removing unit to remove a part of the offset voltage according to an offset code relative to the offset voltage based on a remaining signal to thereby generate a corrected remaining signal.

### CROSS-REFERENCE TO RELATED APPLICATION

This application claims the benefit of Korean Patent Application No. 10-2007-0139224, filed on Dec. 27, 2007, in the Korean Intellectual Property Office, the entire disclosure of which is incorporated herein by reference.

### BACKGROUND OF THE INVENTION

1. Field of the Invention

The present invention relates to a technique for removing an offset voltage in an analog-to-digital pipeline converter.

2. Description of Related Art

Markets relative to display apparatuses providing images having a relatively high resolution have been rapidly developing. In order to provide the high resolution images, analog signals are required to be converted into digital signals without errors.

Currently, studies for an analog-to-digital pipeline converter having a high operation speed and a low power consumption have been actively made. The analog-to-digital pipeline converter sequentially converts analog signals into digital signals through stepwise converters, that is, a plurality of lower function blocks.

For example, a first step converter extracts digital signals of upper 2 bits with respect to input signals, and the remaining stepwise converters sequentially extract 2 bit-digital signals with respect to the input signals.

In this instance, the stepwise converter includes at least one operational amplifier and various electronic components, and thereby signals generated from the stepwise converters include an offset voltage. In addition, input signals of the analog-to-digital converter also include the offset voltage. Due to the offset voltage, the analog signals may be converted into inaccurate digital signals, or a voltage exceeding a useable voltage range may be generated. Also, a dynamic range of the input signals may be disadvantageously reduced due to the offset voltage included in the input signals.

In order to remove the above-described offset voltage at a time after all digital signals are generated through stepwise converters, a plurality of capacitors having different sizes is needed. For example, in a case of an 8-bit analog-to-digital converter, capacitors having sizes of 2⁰C, 2¹C, 2²C, 2³C, 2⁴C, 2⁵C, 2⁶C, and 2⁷C [F] are needed. However, as the size of the capacitor increases, it becomes more difficult to reduce a size of a circuit, and a nonlinear property of the circuit disadvantageously increases.

Accordingly, there arises a need for a technique that may effectively remove the offset voltage while not excessively increasing the size of the capacitor.

### SUMMARY OF THE INVENTION

An aspect of the present invention provides a technique that may sequentially remove an offset voltage in an analog-to-digital pipeline converter, thereby effectively removing the offset voltage without using a large sized-capacitor.

An aspect of the present invention provides a technique that may reduce, using operating characteristics of full scaling mapping of an analog-to-digital pipeline converter, a size of a capacitor used for removing an offset voltage.

An aspect of the present invention provides a technique that may reduce a size of a capacitor, thereby reducing a size of a circuit, and also reducing a nonlinear property of the circuit.

According to an aspect of the present invention, there is provided a device of stepwise eliminating an offset voltage in an analog-to-digital pipeline converter, the device including: a sub analog-to-digital converter to convert an input signal inputted from a preceding stage into a first digital signal; a sub digital-to-analog converter to convert the first digital signal into a first analog signal; and an offset removing unit to remove a part of the offset voltage according to an offset code relative to the offset voltage based on a remaining signal to thereby generate a corrected remaining signal. In this instance, the remaining signal may be a difference between the input signal and the first analog signal.

According to an aspect of the present invention, there is provided an analog-to-digital pipeline converter, the converter including: a first step converter to convert an input signal into a first digital signal, to convert the first digital signal into a first analog signal, to remove a part of an offset voltage according to an offset code relative to the offset voltage based on a first remaining signal to thereby generate a first corrected remaining signal, and to amplify the first corrected remaining signal to thereby generate a first output signal; and a second step converter to convert the first output signal into a second digital signal, to convert the second digital signal into a second analog signal, to remove a part of the offset voltage according to the offset code based on a second remaining signal to thereby generate a second corrected remaining signal, and to amplify the second corrected remaining signal to thereby generate a second output signal. In this instance, the first remaining signal may be a difference between the input signal and the first analog signal, and the second remaining signal may be a difference between the first output signal and the second analog signal.

According to an aspect of the present invention, there is provided a method of operating an analog-to-digital pipeline converter, the method including: converting an input signal into a first digital signal by a first step converter, and converting the first digital signal into a first analog signal; removing, by a first step converter, a part of an offset voltage according to an offset code relative to the offset voltage based on a first remaining signal to thereby generate a first corrected remaining signal, and amplifying the first corrected remaining signal to thereby generate a first output signal; converting the first output signal into a second digital signal by a second step converter, and converting the second digital signal into a second analog signal; and removing, by the second step converter, a part of the offset voltage according to the offset code based on a second remaining signal to thereby generate a second corrected remaining signal, and amplifying the second corrected remaining signal to thereby generate a second output signal. In this instance, the first remaining signal may be a difference between the input signal and the first analog signal, and the second remaining signal may be a difference between the first output signal and the second analog signal.

According to an aspect of the present invention, there is provided a method of operating a device of stepwise eliminating an offset voltage in an analog-to-digital pipeline converter, the method including: converting an input signal inputted from a preceding stage into a first digital signal; converting the first digital signal into a first analog signal; and removing a part of the offset voltage according to an offset code relative to the offset voltage based on a remaining signal to thereby generate a corrected remaining signal. In this instance, the remaining signal may be a difference between the input signal and the first analog signal.

### BRIEF DESCRIPTION OF THE DRAWINGS

The above and other aspects of the present invention will become apparent and more readily appreciated from the following detailed description of certain exemplary embodiments of the invention, taken in conjunction with the accompanying drawings of which:

FIG. 1 is a block diagram illustrating an analog-to-digital pipeline converter according to an exemplary embodiment of the present invention;

FIG. 2 is a block diagram illustrating an example of an N-th step converter illustrated in FIG. 1;

FIG. 3 illustrates a circuit for removing an offset voltage according to an exemplary embodiment of the present invention; and

FIG. 4 is an operation flowchart illustrating a method of operating an analog-to-digital pipeline converter according to an exemplary embodiment of the present invention.

### DETAILED DESCRIPTION OF EXEMPLARY EMBODIMENTS

Reference will now be made in detail to exemplary embodiments of the present invention, examples of which are illustrated in the accompanying drawings, wherein like reference numerals refer to the like elements throughout. The exemplary embodiments are described below in order to explain the present invention by referring to the figures.

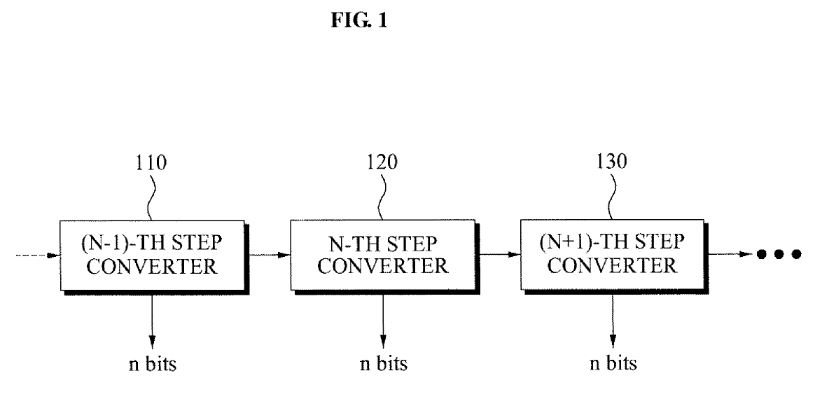

FIG. 1 is a block diagram illustrating an analog-to-digital pipeline converter according to an exemplary embodiment of the present invention.

Referring to FIG. 1, the analog-to-digital pipeline converter according to the present exemplary embodiment includes a plurality of stepwise converters 110, 120, and 130. In this instance, the respective stepwise converters 110, 120, and 130 sequentially output n-bit digital signals.

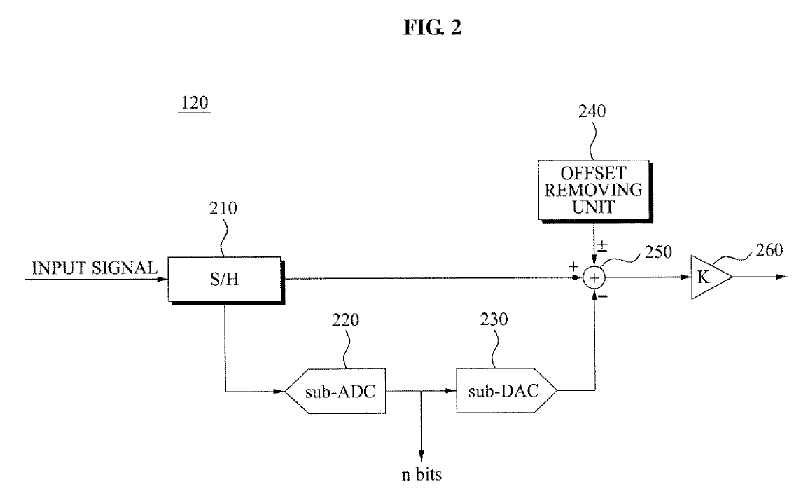

A configuration of removing an offset voltage will be described in detail with reference to FIGS. 2 to 4, and thus descriptions of the configuration of removing an offset voltage will be omitted in the description of FIG. 1.

Hereinafter, n is assumed to be ‘2’. In this instance, an (N−1)-th step converter 110 may output any one of ‘00’, ‘01’, ‘10’, and ‘11’ as an (N−1)-th digital signal with respect to an input signal, and generate an (N−1)-th remaining signal, that is, a difference between the input signal and an (N−1)-th analog signal corresponding to the (N−1)-th digital signal. Also, the (N−1)-th step converter 110 may amplify the (N−1)-th remaining signal four times to generate an (N−1)-th output signal, and transmit the generated (N−1)-th output signal to the N-th step converter 120.

In this instance, the N-th step converter 120 may receive the (N−1)-th output signal of the (N−1)-th step converter 110, and output any one of ‘00’, ‘01’, ‘10’, and ‘11’ as an N-th digital signal with respect to the received (N−1)-th output signal. Also, the N-th step converter 120 may generate an N-th remaining signal, that is, a difference between the (N−1)-th output signal and an N-th analog signal corresponding to the N-th digital signal. Also, the N-th step converter 120 may amplify the N-th remaining signal four times to generate an N-th output signal, and transmit the generated N-th output signal to an (N+1)-th step converter 130.

Also, the (N+1)-th step converter 130 may be operated with the same operation principle as that of the N-th step converter 120. However, when a (stepwise) converter connected after the (N+1)-th step converter 130 is absent, the (N+1)-th step converter 130 generates only an (N+1)-th digital signal using the N-th output signal, and does not generate an (N+1)-th remaining signal. This is because the remaining signal is not needed to be generated any more. Hereinafter, it is assumed that a (stepwise) converter connected after the (N+1)-th step converter 130 is absent.

Consequently, three digital signals each sequentially having 2-bit data in a direction from an upper bit to a lower bit are generated through operations of the above-described stepwise converters 110, 120, and 130, and thereby a 6-bit digital signal is generated. In this instance, the 6-bit digital signal may be mapped with any one of 64 voltage sections. Also, a 2-bit digital signal generated from the (N−1)-th step converter 110 may correspond to upper 2-bits of the 6-bit digital signal, and another 2-bit digital signal generated from the (N+1)-th step converter 130 may correspond to lower 2-bits of the 6-bit digital signal.

However, the stepwise converters 110, 120, and 130 may include a variety of electronic components to thereby generate an offset voltage, and the input signal inputted in the analog-to-digital converter may also include the offset voltage. A dynamic range of the input signal may be reduced due to the offset voltage, and thus removal of the offset voltage is needed. When the offset voltage is removed at a time after all digital signals are generated through the stepwise converters 110, 120, and 130, large sized-capacitors may be needed.

For example, in order to remove four bits of an offset voltage all at once, capacitors having sizes of C, 2C, 4C, and 8C [F] may be needed. Specifically, a charge stored in the capacitors having the sizes of C, 2C, 4C, and 8C [F] may be charged or discharged to thereby remove the offset voltage.

In this instance, when a length of a single unit section is 1 mV, a length of 1, 2, 4, and 8 unit sections is 1, 2, 4, and 8 mV, respectively. In this instance, when the capacitors having the sizes of C, 2C, 4C, and SC [F] are connected with the (N+1)-th step converter 130, each of the capacitors may be used for removing offset voltages of 1, 2, 4, and 8 mV. For example, capacitors having sizes of 4C and 8C [F] may be used for removing an offset voltage of 12 mV.

However, large sized-capacitors are needed to remove the offset voltage at a time, and thereby it is difficult to reduce a size of a circuit, and nonlinear characteristics of the circuit are disadvantageously increased.

However, according to an exemplary embodiment of the invention, when the offset voltages are removed through operations of the respective stepwise converters 110 and 120 instead of removing the offset voltage at a time, the needed capacitor's size may be significantly reduced.

Here, it is assumed that the (N−1)-th step converter 110 and the N-th step converter 120 remove the offset voltage using capacitors having sizes of ¼C and ½C [F] before amplifying signals. In this instance, the N-th step converter 120 may remove offset voltages corresponding to 1 and 2 unit sections using the capacitors having sizes of ¼C and ½C [F]. This is because the N-th step converter 120 transmits the N-th output signal obtained by amplifying the N-th remaining signal four times to the (N+1)-th step converter 130.

Accordingly, the N-th step converter 120 may remove in advance the offset voltage using relatively small sized-capacitors before amplifying the N-th remaining signal four times to generate the N-th output signal.

Similarly, the (N-1)-th step converter 110 may reduce offset voltages corresponding to 4 and 8 unit sections in the (N−1)-th remaining signal using the capacitors having sizes of ¼C and ½C [F].

Consequently, according to an exemplary embodiment of the invention, offset voltages corresponding to 1, 2, 4, and 8 unit sections may be removed using each of two capacitors having the sizes of ¼C and ½C [F]. Thus, according to an exemplary embodiment of the invention, the offset voltage may be effectively removed without continuously increasing the sizes of the capacitors by multiples of 2.

FIG. 2 is a block diagram illustrating an example of an N-th step converter 120 illustrated in FIG. 1.

Referring to FIG. 2, the N-th step converter 120 includes a Sample Holder (S/H) 210, a sub analog-to-digital converter 220, a sub digital-to-analog converter 230, an offset removing unit 240, an adder 250, and an amplifier 260.

The S/H 210 receives an input signal from the (N−1)-th step converter (not illustrated in FIG. 2), and then samples and holds the received input signal. In this instance, the S/H 210 outputs the input signal through the sub analog-to-digital converter 220 and the adder 250.

Also, the sub analog-to-digital converter 220 receives the input signal and converts the input signal into an N-th digital signal. In this instance, the sub analog-to-digital converter 220 divides a voltage section into a plurality of unit sections, and selects a unit section corresponding to the input signal from among the plurality of unit sections. In this instance, an n-bit digital code corresponding to the selected unit section is outputted as the N-th digital signal.

Also, the sub digital-to-analog converter 230 converts the N-th digital signal into an N-th analog signal, and outputs the N-th analog signal through the adder 250.

Also, the offset removing unit removes a part of an offset voltage generated in accordance with an offset code from a remaining signal to thereby generate a corrected remaining signal. In this instance, the remaining signal is a difference between the input signal and the N-th analog signal.

Although not shown in FIG. 2, it is assumed that the offset voltage may be accurately measured by an external offset voltage device. In this instance, it is assumed that the offset code may be generated in accordance with the measured offset voltage, and the generated offset code may be adequately provided to a plurality of stepwise converters. Specifically, a technical aspect of the invention is to stepwise remove the offset voltage using the generated offset code which is different from generating the offset code, and thus detailed descriptions concerning a configuration for measuring the offset voltage will be herein omitted.

In this instance, the offset removing unit 240 may adjust an amount of the charge accumulated in the plurality of capacitors, and remove a part of the offset voltage from the remaining signal to thereby generate a corrected remaining signal. In particular, the offset removing unit 240 may switch the plurality of capacitors in accordance with the offset code to thereby adjust the amount of the charge accumulated in the plurality of capacitors.

Consequently, the adder 250 outputs, through the amplifier 260, the corrected remaining signal obtained by removing the part of the offset voltage from the remaining signal, that is, a difference between the input signal and the N-th analog signal.

Also, the amplifier 260 amplifies the corrected remaining signal to generate an output signal, and transmits the generated output signal to a stepwise converter corresponding to the next stage.

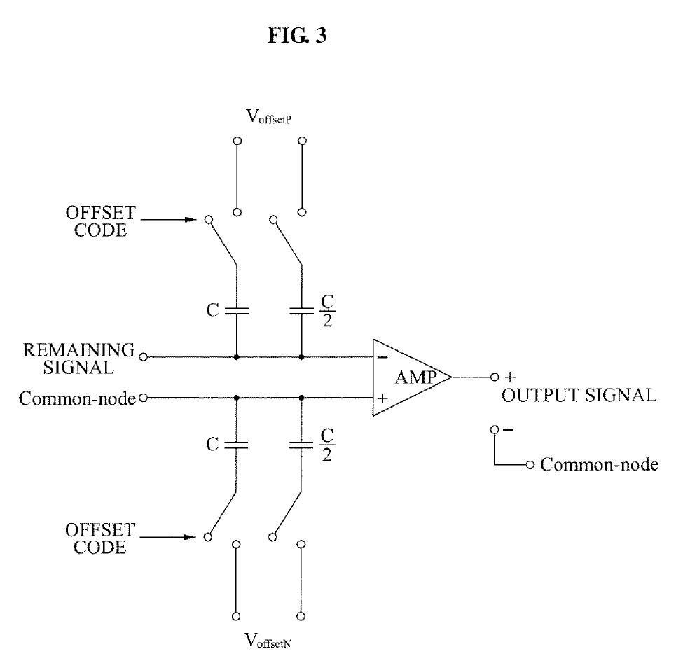

FIG. 3 illustrates a circuit for removing an offset voltage according to an exemplary embodiment of the present invention.

Referring to FIG. 3, a remaining signal is inputted to a (−) input terminal of an amplifier (AMP). Also, a (+) input terminal and common node of the AMP are connected with each other.

Also, (−) and (+) input terminals of the AMP are connected with capacitors having sizes of C and ½C [F]. In this instance, the capacitors having the sizes of C and ½C [F] are switched in accordance with an offset code to be connected with V_{offsetP} or V_{offsetN}, and an amount of a charge stored in the capacitors having the sizes of C and ½C [F] may be adjusted in accordance with the offset code.

Hereinafter, it is assumed that a circuit illustrated in FIG. 3 is mounted in each of the (N−1)-th step converter and N-th step converter of FIG. 1, n is ‘2’, and a 6-bit digital signal is generated. In this instance, it is assumed that capacitors having sizes of C and C/2 [F] included in each of the (N−1)-th step converter and the N-th step converter are switched on with V_{offsetP}, and a length of an entire voltage section is 2 V.

In this instance, when the 6-bit digital signal is generated, an input signal inputted to the (N−1)-th step converter corresponds to any one unit section of 2⁶=64 numbered-unit sections. Also, a length of a single unit section is 2/64=31.25 mV.

In this instance, when each of the capacitors having the sizes of C and C/2 [F] included in the N-th step converter removes an offset voltage corresponding to 2 and 1 unit sections (62.5 mV and 31.25 mV), each of capacitors having sizes of C and C/2 [F] included in the (N+1)-th step converter may remove an offset voltage corresponding to 8 and 4 unit sections (125 mV and 62.5 mV).

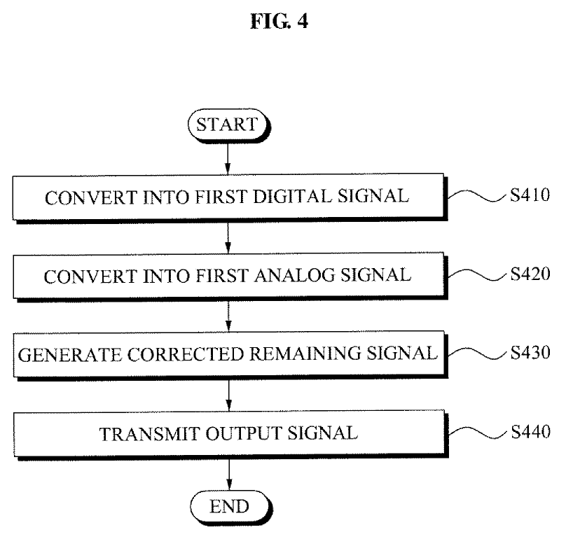

FIG. 4 is an operation flowchart illustrating a method of operating an analog-to-digital pipeline converter according to an exemplary embodiment of the present invention.

Referring to FIG. 4, in operation S410, a method of operating a stepwise converter according to an exemplary embodiment of the invention converts an input signal inputted from a preceding stage into a first digital signal.

Next, in operation S420, the method converts the first digital signal into a first analog signal.

In operation S430, the method removes a part of an offset voltage in accordance with an offset code relative to the offset voltage based on a remaining signal to thereby generate a corrected remaining signal. In this instance, the remaining signal is a difference between the input signal and the first analog signal.

In this instance, operation S430 for generating the corrected remaining signal may be an operation for adjusting an amount of a charge accumulated in a plurality of capacitors in accordance with the offset code and removing the part of the offset voltage to thereby generate the corrected remaining signal.

In this instance, operation S430 for generating the corrected remaining signal may be an operation for switching the plurality of capacitors in accordance with the offset code, and removing the part of the offset voltage to thereby generate the corrected remaining signal.

In operation S440, the method amplifies the corrected remaining signal.

In this instance, operation S440 for amplifying the corrected remaining signal may be an operation for amplifying the corrected remaining signal to generate an output signal, and transmitting the generated output signal to the next stage.

Also, although not shown in FIG. 4, a method of operating an analog-to-digital pipeline converter includes converting an input signal into a first digital signal by a first step converter, and converting the first digital signal into a first analog signal, removing, by a first step converter, a part of an offset voltage according to an offset code relative to the offset voltage based on a first remaining signal to thereby generate a first corrected remaining signal, and amplifying the first corrected remaining signal to thereby generate a first output signal, converting the first output signal into a second digital signal by a second step converter, and converting the second digital signal into a second analog signal, and removing, by the second step converter, a part of the offset voltage according to the offset code based on a second remaining signal to thereby generate a second corrected remaining signal, and amplifying the second corrected remaining signal to thereby generate a second output signal. In this instance, the first remaining signal is a difference between the input signal and the first analog signal, and the second remaining signal is a difference between the first output signal and the second analog signal.

Also, the method of operating the analog-to-digital pipeline converter further includes converting the second output signal into a third digital signal by a third step converter, and converting the third digital signal into a third analog signal; and removing, by the third step converter, a part of the offset voltage according to the offset code based on a third remaining signal to thereby generate a third corrected remaining signal, and amplifying the third corrected remaining signal to thereby generate a third output signal. In this instance, the second remaining signal is a difference between the second output signal and the third analog signal.

In this instance, the first step converter generates the first corrected remaining signal using a first capacitor group including a plurality of capacitors, and the second step converter generates a second corrected remaining signal using a second capacitor group matched with the first capacitor group.

The method of operating a device of stepwise eliminating the offset voltage and the method of operating an analog-to-digital pipeline converter according to the above-described exemplary embodiments of the present invention may be recorded in computer-readable media including program instructions to implement various operations embodied by a computer. The media may also include, alone or in combination with the program instructions, data files, data structures, and the like. The media and program instructions may be those specially designed and constructed for the purposes of the present invention. Examples of computer-readable media include magnetic media such as hard disks, floppy disks, and magnetic tape; optical media such as CD ROM disks and DVDs; magneto-optical media such as optical disks; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of the above-described exemplary embodiments of the present invention.

As described above, according to the present invention, the offset voltage in the analog-to-digital pipeline converter may be sequentially removed, thereby effectively removing the offset voltage even without using a large sized-capacitor

According to the present invention, the size of the capacitor used for removing the offset voltage may be reduced using operating characteristics of full scaling mapping of an analog-to-digital pipeline converter.

According to the present invention, the size of the capacitor may be reduced, thereby reducing a size of a circuit, and also reducing a nonlinear property of the circuit.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A device of stepwise eliminating an offset voltage in an analog-to-digital pipeline converter, the device comprising:
a sub analog-to-digital converter to convert an input signal inputted from a preceding stage into a first digital signal;
a sub digital-to-analog converter to convert the first digital signal into a first analog signal; and
an offset removing unit to remove a part of the offset voltage according to an offset code relative to the offset voltage based on a remaining signal to thereby generate a corrected remaining signal,
wherein the remaining signal is a difference between the input signal and the first analog signal.

2. The device of claim 1, wherein the offset removing unit adjusts a charge amount accumulated in a plurality of capacitors according to the offset code, and removes the part of the offset voltage to thereby generate the corrected remaining signal.

3. The device of claim 1, wherein the offset removing unit switches a plurality of capacitors according to the offset code, and removes the part of the offset voltage to thereby generate the corrected remaining signal.

4. The device of claim 1, further comprising:
an amplifier to amplify the corrected remaining signal.

5. The device of claim of 4, wherein the amplifier amplifies the corrected remaining signal to generate an output signal, and transmits the generated output signal to a following stage.

6. An analog-to-digital pipeline converter, the converter comprising:
a first step converter to convert an input signal into a first digital signal, to convert the first digital signal into a first analog signal, to remove a part of an offset voltage according to an offset code relative to the offset voltage based on a first remaining signal to thereby generate a first corrected remaining signal, and to amplify the first corrected remaining signal to thereby generate a first output signal; and
a second step converter to convert the first output signal into a second digital signal, to convert the second digital signal into a second analog signal, to remove a part of the offset voltage according to the offset code based on a second remaining signal to thereby generate a second corrected remaining signal, and to amplify the second corrected remaining signal to thereby generate a second output signal,
wherein the first remaining signal is a difference between the input signal and the first analog signal, and the second remaining signal is a difference between the first output signal and the second analog signal.

7. The converter of claim 6, further comprising:
a third step converter to convert the second output signal into a third digital signal, convert the third digital signal into a third analog signal, to remove a part of the offset voltage according to the offset code based on a third remaining signal to thereby generate a third corrected remaining signal, and to amplify the third corrected remaining signal to thereby generate a third output signal,
wherein the second remaining signal is a difference between the second output signal and the third analog signal.

8. The converter of claim 7, wherein the first step converter generates the first corrected remaining signal using a first capacitor group including a plurality of capacitors, and the second step converter generates a second corrected remaining signal using a second capacitor group matched with the first capacitor group.

9. A method of operating an analog-to-digital pipeline converter, the method comprising:
converting an input signal into a first digital signal by a first step converter and converting the first digital signal into a first analog signal;
removing, by a first step converter, a part of an offset voltage according to an offset code relative to the offset voltage based on a first remaining signal to thereby generate a first corrected remaining signal, and amplifying the first corrected remaining signal to thereby generate a first output signal;
converting the first output signal into a second digital signal by a second step converter, and converting the second digital signal into a second analog signal; and
removing, by the second step converter, a part of the offset voltage according to the offset code based on a second remaining signal to thereby generate a second corrected remaining signal, and amplifying the second corrected remaining signal to thereby generate a second output signal,
wherein the first remaining signal is a difference between the input signal and the first analog signal, and the second remaining signal is a difference between the first output signal and the second analog signal.

10. The method of claim 9, further comprising:
converting the second output signal into a third digital signal by a third step converter, and converting the third digital signal into a third analog signal; and
removing, by the third step converter, a part of the offset voltage according to the offset code based on a third remaining signal to thereby generate a third corrected remaining signal, and amplifying the third corrected remaining signal to thereby generate a third output signal,
wherein the second remaining signal is a difference between the second output signal and the third analog signal.

11. The method of claim 9, wherein the first step converter generates the first corrected remaining signal using a first capacitor group including a plurality of capacitors, and the second step converter generates a second corrected remaining signal using a second capacitor group matched with the first capacitor group.

12. A method of operating a device of stepwise eliminating an offset voltage in an analog-to-digital pipeline converter, the method comprising:
converting an input signal inputted from a preceding stage into a first digital signal;
converting the first digital signal into a first analog signal; and
removing a part of the offset voltage according to an offset code relative to the offset voltage based on a remaining signal to thereby generate a corrected remaining signal,
wherein the remaining signal is a difference between the input signal and the first analog signal.

13. The method of claim 12, wherein the removing adjusts a charge amount accumulated in a plurality of capacitors according to the offset code, and removes a part of the offset voltage to thereby generate the corrected remaining signal.

14. The method of claim of 12, wherein the removing switches a plurality of capacitors according to the offset code, and removes the part of the offset voltage to thereby generate the corrected remaining signal.

15. The method of claim 12, further comprising:
amplifying the corrected remaining signal.

16. The method of claim 12, wherein the amplifying amplifies the corrected remaining signal to thereby generate an output signal, and transmits the generated output signal to a following stage.
